(19) United States
(12) Patent Application Publication
(10) Pub. No.: US 2023/0187304 A1
(43) Pub. Date: Jun. 15, 2023

(54) SEMICONDUCTOR DEVICE AND SEMICONDUCTOR DEVICE MANUFACTURING METHOD

(71) Applicant: KIOXIA CORPORATION, Tokyo (JP)

(72) Inventor: Taku NISHIYAMA, Yokohama Kanagawa (JP)

(21) Appl. No.: 17/877,419

(22) Filed: Jul. 29, 2022

(30) Foreign Application Priority Data
Dec. 14, 2021 (JP) 2021-202615

(51) Int. Cl. H01L 23/367; H01L 21/48; H01L 23/00; H01L 23/10

(52) U.S. Cl. CPC H01L 23/3675; H01L 21/4853; H01L 24/13; H01L 23/10; H01L 2224/13021; H01L 2224/131

(57) ABSTRACT

A semiconductor device includes a substrate, an insulating layer that is provided on the substrate and has multiple openings, a semiconductor chip that is provided on the substrate and has a first face, on which a semiconductor element is formed, and a second face, which opposes the first face and faces the substrate, multiple protrusions provided on the substrate in positions corresponding to the multiple openings of the insulating layer between the substrate and the second face, a height of the multiple protrusions in a direction vertical to the second face is greater than a height of the insulating layer in a direction vertical to the second face, and a bonding layer that is provided between the substrate and the second face to bond the substrate and the semiconductor chip, and has a thermal conductivity that is more than 1 W/(m·K).

### CROSS-REFERENCE TO RELATED APPLICATION(S)

This application is based upon and claims the benefit of priority from Japanese Patent Application No. 2021-202615, filed Dec. 14, 2021, the entire contents of which are incorporated herein by reference.

### FIELD

Embodiments described herein relate generally to a semiconductor device and a semiconductor device manufacturing method.

### BACKGROUND

A semiconductor device having a heat dissipating structure is known.

### DESCRIPTION OF THE DRAWINGS

FIG. 1 is a diagram showing one example of a structure of a semiconductor device according to a first embodiment.

FIG. 2 is an enlarged view of one example of a structure of a semiconductor device according to the first embodiment.

FIG. 3 is an enlarged view of another example of a structure of a semiconductor device according to the first embodiment.

FIGS. 4A-4F illustrate one example of a semiconductor device manufacturing method according to the first embodiment.

FIG. 5 is an enlarged view of one example of a structure of a semiconductor device according to a second embodiment.

FIGS. 6A-6B illustrate one example of a semiconductor device manufacturing method according to the second embodiment.

FIG. 7 is an enlarged view of one example of a structure of a semiconductor device according to a third embodiment.

FIGS. 8A-8C illustrate one example of a semiconductor device manufacturing method according to the third embodiment.

FIG. 9 is a schematic plan view showing one example of a schematic configuration of a semiconductor device according to a fourth embodiment.

FIG. 10 is a schematic plan view showing another example of a schematic configuration of a semiconductor device according to the fourth embodiment.

FIG. 11 is a schematic plan view showing still another example of a schematic configuration of a semiconductor device according to the fourth embodiment.

FIG. 12 is a diagram showing one example of a structure of a semiconductor device according to a fifth embodiment.

### DETAILED DESCRIPTION

Embodiments provide an improvement in heat dissipating efficiency of a semiconductor device in which a semiconductor chip is mounted.

In general, according to one embodiment, a semiconductor device includes a substrate, an insulating layer that is provided on the substrate and has multiple openings, a semiconductor chip that is provided on the substrate and has a first face, on which a semiconductor element is formed, and a second face, which opposes the first face and faces the substrate, multiple protrusions provided on the substrate in positions corresponding to the multiple openings of the insulating layer between the substrate and the second face, a height of the multiple protrusions in a direction vertical to the second face is greater than a height of the insulating layer in a direction vertical to the second face, and a bonding layer that is provided between the substrate and the second face, can bond the substrate and the semiconductor chip, and has a thermal conductivity that is more than 1 W/(m·K).

Hereafter, embodiments for implementing the disclosure will be described, with reference to the drawings. The drawings are schematic, and a relationship between a thickness and a planar dimension, ratios of layer thicknesses, and the like, may differ from actual ones. Also, in the embodiments, identical reference signs will be given to elements that are substantially identical, and a redundant description will be omitted.

### First Embodiment

### Configuration

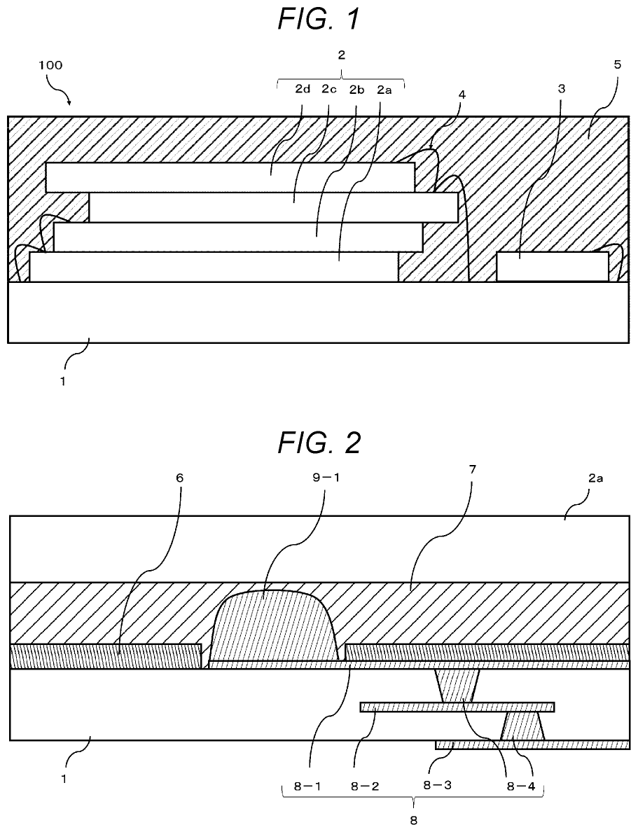

A configuration of a semiconductor device of a first embodiment will be described, with reference to FIGS. 1 to 3.

FIG. 1 is a diagram showing one example of a structure of a semiconductor device according to the first embodiment. A semiconductor device 100 shown in FIG. 1 includes a substrate 1, multiple semiconductor chips 2a, 2b, 2c, and 2d, a memory controller 3, a bonding wire 4, and a sealing resin layer 5.

The substrate 1 is formed using, for example, a multilayer wiring board, or a silicon chip or the like. A connection pad (not shown) that can be electrically connected to, for example, an external connection terminal (not shown), the semiconductor chip 2, and the memory controller 3, is provided on the substrate 1.

The multiple semiconductor chips 2a, 2b, 2c, and 2d are provided on a main face of the substrate 1. The multiple semiconductor chips 2a, 2b, 2c, and 2d are stacked and bonded to each other across a bonding layer, in such a way that one portion of each lower chip is overlapped by the one above. In the embodiment, four semiconductor chips 2a, 2b, 2c, and 2d are stacked, but the number of semiconductor chips to be stacked is not limited to this. Hereafter, when not differentiating among the chips, the multiple semiconductor chips 2a, 2b, 2c, and 2d will be collectively referred to as the semiconductor chip 2. A NAND-type flash memory, for example, may be used as the semiconductor chip 2.

The semiconductor chip 2 has a first face and a second face. A semiconductor element is formed on the first face of the semiconductor chip 2, and corresponds to an upper face of the semiconductor chip 2 in FIG. 1. The semiconductor element may be formed on the first face side of the semiconductor chip 2. The second face of the semiconductor chip 2 is a face on a side opposite to that of the first face, faces the substrate 1, and corresponds to a lower face of the semiconductor chip 2 in FIG. 1. The semiconductor chip 2 is, for example, electrically connected to the substrate 1 by a connection pad on the substrate 1 and an electrode pad (not shown) provided on the first face of the semiconductor chip 2.

The memory controller 3 is provided on the main face of the substrate 1. For example, the memory controller 3 is fixed onto the substrate 1 using an adhesive (not shown). The memory controller 3 can control an operation such as a writing of data into or a reading of data from the semiconductor chip 2. An electrode pad (not shown), for example, is provided on the memory controller 3, and the memory controller 3 is electrically connected to the substrate 1 by the electrode pad and a connection pad on the substrate 1. The memory controller 3 may be provided above the semiconductor chip 2, or between the substrate 1 and the semiconductor chip 2.

The bonding wire 4 connects an electrode pad provided on the first face of the semiconductor chip 2 and a connection pad provided on the substrate 1, thereby electrically connecting the substrate 1 and the semiconductor chip 2. Also, the bonding wire 4 connects an electrode pad provided on the memory controller 3 and a connection pad provided on the substrate 1, thereby electrically connecting the substrate 1 and the memory controller 3. Because of this, the semiconductor chip 2 and the memory controller 3 are electrically connected via the substrate 1. The bonding wire 4 is formed using, for example, copper, gold, or aluminum.

The sealing resin layer 5 seals the semiconductor chip 2, the memory controller 3, and the bonding wire 4. The sealing resin layer 5, for example, includes an inorganic filler, and is formed using a sealing resin in which the inorganic filler and an organic resin are mixed. The inorganic filler is, for example, silicon dioxide (SiO₂). A transfer molding method and a compression molding method, for example, may be used as methods of forming the sealing resin layer 5.

FIG. 2 is an enlarged view of one example of a structure of a semiconductor device according to the first embodiment. As shown in FIG. 2, an insulating layer 6, a bonding layer 7, wiring 8, and a protrusion 9-1 are provided between the substrate 1 and the second face of the semiconductor chip 2a, which is the nearest chip to the substrate 1 among the stacked multiple semiconductor chips 2a, 2b, 2c, and 2d. In this embodiment, the description is provided for between the substrate 1 and the second face of the semiconductor chip 2a. However, it may also be applied for between the substrate 1 and the memory controller 3.

The insulating layer 6 is provided on the substrate 1, and has multiple openings. The multiple openings are formed in, for example, connection pad positions or spaces in wiring of the substrate 1. The multiple openings of the insulating layer 6 are formed using, for example, direct imaging. An insulating resin material, for example, may be used for the insulating layer 6.

The bonding layer 7 is provided between the substrate 1 and the semiconductor chip 2a, and can bond the insulating layer 6 and the semiconductor chip 2a. When assembling the semiconductor device 100, for example, the bonding layer 7 is applied to the second face of the semiconductor chip 2a, and the semiconductor chip 2a is pressed against the substrate 1 from above the insulating layer 6, thereby causing the semiconductor chip 2a and the substrate 1 to be bonded. For example, a bonding layer 7 may have a thermal conductivity that is more than 1 W/(m·K). The bonding layer 7 may also contain filler of inorganic material.

The wiring 8 is formed using, for example, copper. The wiring 8 has, for example, wiring 8-1, which is provided on the main face of the substrate 1 in such a way that an upper portion is covered by the insulating layer 6, wiring 8-2 embedded in an interior of the substrate 1, wiring 8-3 provided on a face of the substrate 1 on a side opposite to that of the main face, and wiring 8-4. The wiring 8-4 electrically connects the wiring 8-1 and the wiring 8-2. Also, the wiring 8-4 electrically connects the wiring 8-2 and the wiring 8-3. That is, the wiring 8-1 and the wiring 8-3 are electrically connected via the wiring 8-2 and the wiring 8-4. Hereafter, when not differentiating the wirings, the wirings 8-1, 8-2, 8-3, and 8-4 will be collectively referred to as the wiring 8.

The protrusion 9-1 is provided between the substrate 1 and the second face of the semiconductor chip 2a, in positions on the substrate 1 corresponding to the multiple openings of the insulating layer 6. A material of the protrusion 9-1 is a material that can dissipate heat. It is preferable that the protrusion 9-1 contains, for example, a material having high heat conductivity, such as metal, which is advantageous in heat dissipation. The protrusion 9-1 is connected to the wiring 8-1 exposed in an opening, and is provided electrically independent of the wiring 8 that electrically connects the semiconductor chip 2 and an external connection terminal. That is the protrusion 9-1 is connected to a wiring that is in an electrically floating state. Also, an arrangement may be such that the protrusion 9-1 can be connected to a ground (ground voltage) via the wiring 8. In the present embodiment, the protrusion 9-1 is formed using copper. Although not shown, multiple the protrusion 9-1 are provided between the substrate 1 and the second face of the semiconductor chip 2a. Also, a height of the protrusion 9-1 in a direction approximately vertical to the second face of the semiconductor chip 2a is greater than a height of the insulating layer 6 in a direction approximately vertical to the second face of the semiconductor chip 2a. Although the protrusion 9-1 is formed using copper in the present embodiment, the protrusion 9-1 may be formed using a metal such as gold or a solder. The protrusion 9-1 may be, for example, a pillar form mounted part or a bump.

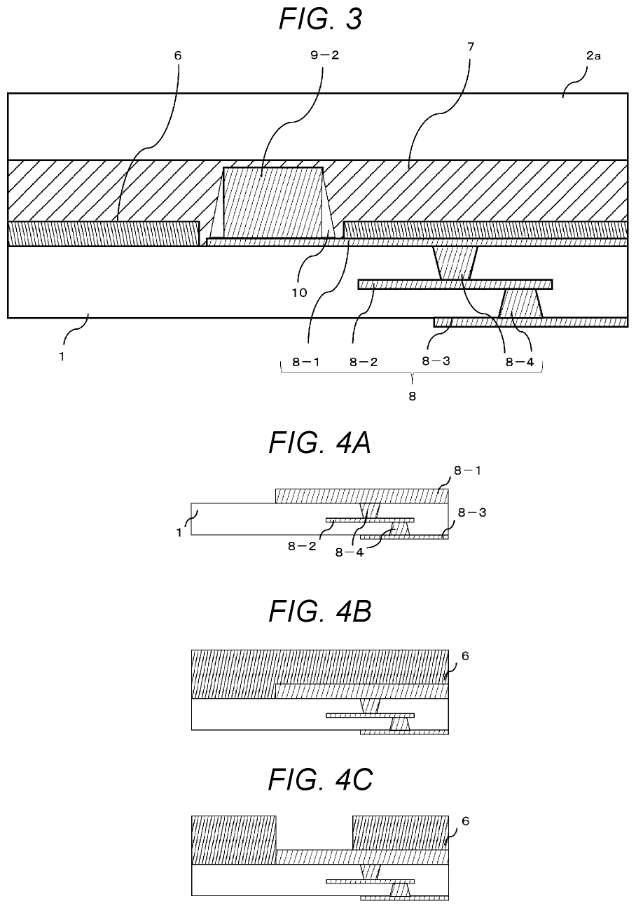

FIG. 3 is an enlarged view of another example of a structure of a semiconductor device according to the first embodiment. In FIG. 3, a pillar-shaped mounted part is used as a protrusion 9-2. When using a pillar-shaped mounted part as the protrusion 9-2, the protrusion 9-2 may be mounted and fixed by, for example, a bonding portion 10. The bonding portion 10 is, for example, a solder.

### Manufacturing Method

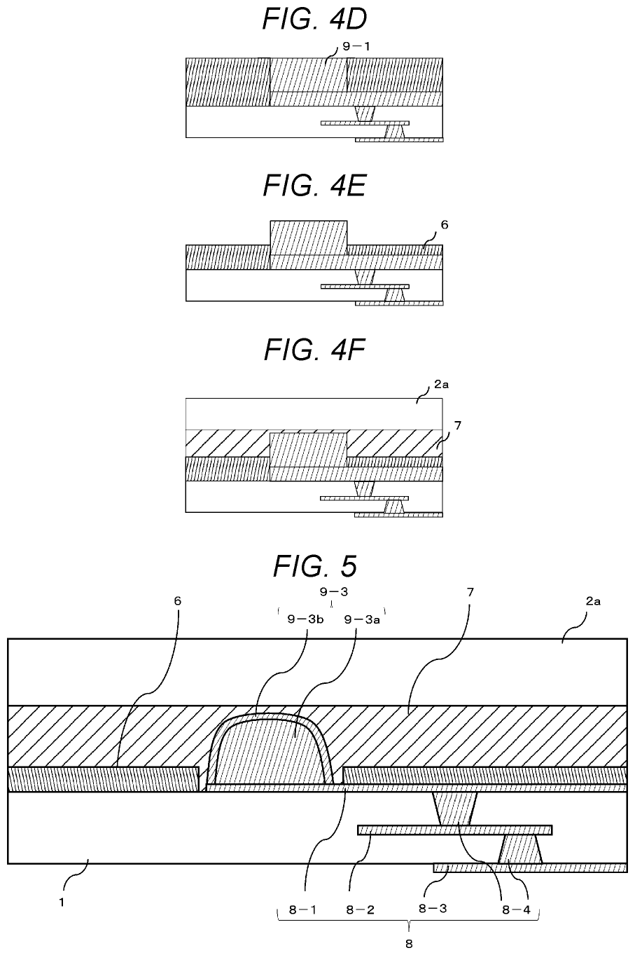

A semiconductor device manufacturing method of the first embodiment will be described, with reference to FIGS. 4A to 4F. FIGS. 4A to 4F are drawings showing one example of a semiconductor device manufacturing method according to the first embodiment. Although multiple protrusions are provided between the substrate 1 and the semiconductor chip 2a, one protrusion is shown in FIGS. 4A to 4F.

FIG. 4A is a diagram showing a state in which the wiring 8-1 is formed on the substrate 1. When forming the wiring 8-1, a film of copper that is to form the wiring 8 is formed on the substrate 1. Further, a photoresist is applied on the substrate 1 and on the film of copper formed. After the photoresist is applied to the substrate 1, a pattern of the wiring 8 is transferred using exposure, and the pattern is formed by developing. Further, the copper is etched with the photoresist as a mask, thereby forming the wiring 8-1 (FIG. 4A).

Then, the insulating layer 6 is applied to the substrate 1 on which the wiring 8-1 is formed (FIG. 4B).

Further, multiple openings are formed in the insulating layer 6 on the substrate 1 using, for example, direct imaging followed by etching. Specifically, prior to etching, without using a mask, openings above the insulating layer 6 are formed, for example, by applying a photosensitive layer on the insulating layer 6, directly exposing the photosensitive layer by a laser, and then developing the photosensitive layer (FIG. 4C). The insulating layer 6 itself may be photosensitive. In this case, the photosensitive layer is not applied, and the openings of the insulating layer 6 are formed by directly exposing the insulating layer 6 by the laser and developing the insulating layer 6.

The protrusion 9-1 is formed by, for example, plating in positions on the substrate 1 corresponding to the multiple openings (FIG. 4D).

After the protrusion 9-1 is formed, the insulating layer 6 is thinned (FIG. 4E). For example, the insulating layer 6 can be thinned by immersing the insulating layer 6 in a dip tank containing a chemical, and washing a portion of the insulating layer 6 that has reacted with the chemical.

The semiconductor chip 2a on whose second face the bonding layer 7 is applied, is bonded to the substrate 1 after carrying out the heretofore described processes (FIG. 4F). Specifically, the semiconductor chip 2a is bonded to the substrate 1 in such a way that the second face of the semiconductor chip 2a faces the substrate 1 across the insulating layer 6 and the protrusion 9-1.

### Advantages

The present embodiment provides multiple protrusions 9-1 between the second face of the semiconductor chip 2a and the substrate 1, and heat emitted by the semiconductor chip 2a can be efficiently dissipated from the second face of the semiconductor chip 2a to the substrate 1 via the protrusion 9-1 and the wiring 8. The structure of the present embodiment can increase heat dissipating efficiency of the semiconductor chip 2 in comparison with a structure in which there is no protrusion 9-1. In particular, although the semiconductor chip of the present embodiment has a type of structure in which there is no electrode on the second face of the semiconductor chip 2a bonded to the substrate 1, it is expected to effectively dissipate heat emitted from the second face because the protrusion 9-1 is provided. Also, as the protrusion 9-1 of the present embodiment is provided between the substrate 1 and the second face of the semiconductor chip 2a, a package thickness of the semiconductor device 100 do not need to be increased. Furthermore, although the height of the protrusion 9-1 in a direction approximately vertical to the second face of the semiconductor chip 2a is greater than the height of the insulating layer 6 in a direction approximately vertical to the second face of the semiconductor chip 2a, the protrusion 9-1 does not come into contact with the second face of the semiconductor chip 2a. Because of this, the semiconductor chip 2a can be prevented from becoming scratched or cracked.

### Second Embodiment

Next, a second embodiment will be described. The second embodiment differs from the first embodiment in that a surface processing is carried out on a protrusion 9-3. Configurations except for a surface processing being carried out on the protrusion 9-3, are the same as in the case of the semiconductor device of the first embodiment.

### Configuration

A configuration of a semiconductor device of the second embodiment will be described, with reference to FIG. 5.

FIG. 5 is an enlarged view of one example of a structure of a semiconductor device according to the second embodiment. As shown in FIG. 5, a surface processing 9-3b is carried out on the protrusion 9-3. The protrusion 9-3 is formed by, for example, the surface processing 9-3b being carried out using nickel and gold on a protrusion 9-3a formed using copper. Metals used in the surface processing 9-3b of the protrusion 9-3 may be other than nickel and gold.

### Manufacturing Method

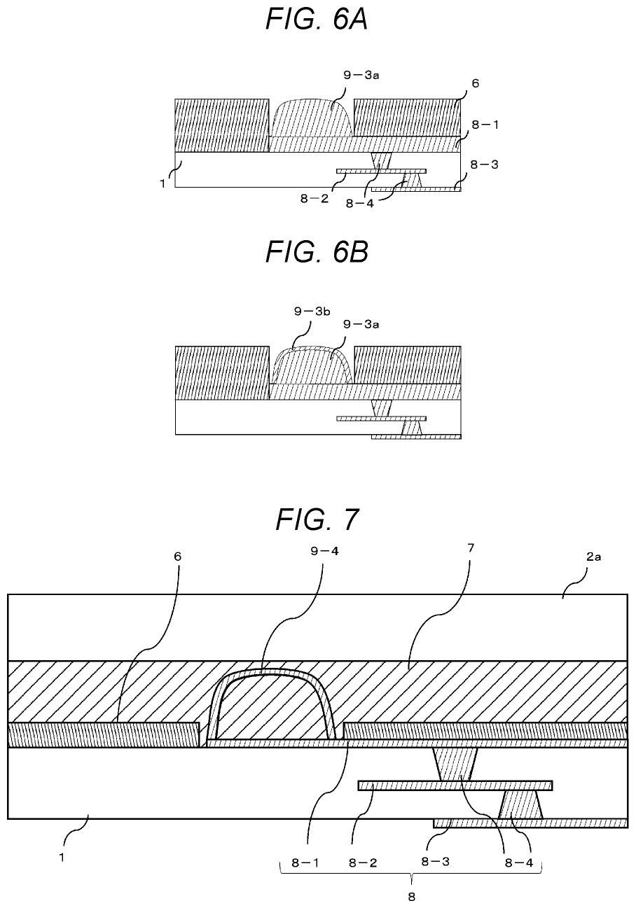

A semiconductor device manufacturing method of the second embodiment will be described, with reference to FIGS. 6A and 6B. FIGS. 6A and 6B are drawings showing one example of a semiconductor device manufacturing method according to the second embodiment. Points that are the same as in the case of the manufacturing method of the first embodiment illustrated in FIGS. 4A to 4F will be omitted.

The manufacturing method as far as the process of forming the multiple openings shown in FIG. 4C is the same.

The copper protrusion 9-3a is formed in the multiple openings (FIG. 6A).

Further, a surface processing of the protrusion 9-3a is carried out using, for example, nickel and gold (FIG. 6B). For example, the surface processing is plating. The surface processing 9-3b of the protrusion 9-3 is formed by this process.

After the surface processing ends, the processes from FIG. 4E onward are carried out, in the same way as in the first embodiment.

### Advantages

According to the second embodiment, the same advantages as in the first embodiment can be obtained. Also, when copper oxidizes, heat conductivity decreases considerably. Although heat conductivities of the nickel and the gold used in the surface processing 9-3b are lower than that of the copper used in the protrusion 9-3a, gold has the highest heat conductivity among metals after copper. Also, gold is less liable to oxidize than copper. That is, the present embodiment is such that while having high heat conductivity in comparison with the first embodiment, oxidation of the copper used in the protrusion 9-3a is restricted, and an increased heat dissipating efficiency can be maintained.

### Third Embodiment

### Configuration

Next, a third embodiment will be described. The third embodiment differs from the first embodiment in that a protrusion 9-4 is formed in an arch form using wire or the like. Configurations except for the protrusion 9-4 being formed in an arch form using wire or the like are the same as in the case of the semiconductor device of the first embodiment.

A configuration of a semiconductor device of the third embodiment will be described, with reference to FIG. 7.

FIG. 7 is an enlarged view of one example of a structure of a semiconductor device according to the third embodiment. As shown in FIG. 7, the protrusion 9-4 is formed in an arch form using wire. The wire is formed using a metal such as copper or gold.

### Manufacturing Method

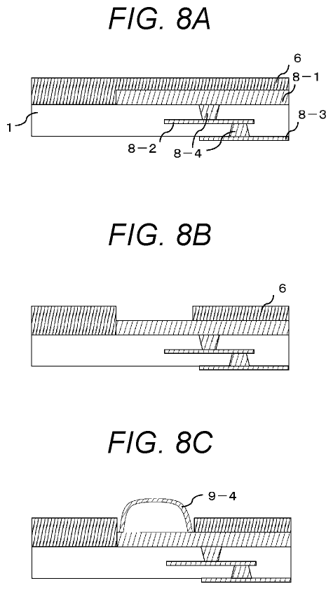

A semiconductor device manufacturing method of the third embodiment will be described, with reference to FIGS. 8A to 8C. FIGS. 8A to 8C are drawings showing one example of a semiconductor device manufacturing method according to the third embodiment. Points that are the same as in the case of the manufacturing method of the first embodiment illustrated in FIGS. 4A to 4F will be omitted.

The manufacturing method as far as the process of forming the wiring 8 shown in FIG. 4A is the same. After the wiring 8 is formed, the insulating layer 6 is applied to the substrate 1 (FIG. 8A). In the present embodiment, the insulating layer 6 is applied thinly in comparison with the case of the first embodiment.

Further, in the same way as in FIG. 4C, openings of the insulating layer 6 are formed by directly exposing a photosensitive layer applied on the insulating layer 6, by the laser, developing the photosensitive layer, and then etching (FIG. 8B).

After the multiple openings are formed, the arch-form protrusion 9-4 is formed using a wire in the multiple openings (FIG. 8C). In the present embodiment, the insulating layer 6 is thin in comparison with the case of the first embodiment. As a result, the arch-form protrusion 9-4 can be formed using wire bonding. Further, in the same way as in FIG. 4F, the semiconductor chip 2a having a second face on which the bonding layer 7 is applied, is bonded to the substrate 1.

### Advantages

According to the third embodiment, efficiency of heat dissipation from the second face of the semiconductor chip 2a to the substrate 1 via the wire protrusion 9-4 formed in an arch form can be increased, and the same advantages as in the first embodiment can be obtained. Also, according to the present embodiment, an amount of metal used in a protrusion structure can be reduced in comparison with the case of the first embodiment.

### Fourth Embodiment

Next, a fourth embodiment will be described. The fourth embodiment differs from the first embodiment in dispositions of multiple protrusions. Hereafter, when not differentiating among the protrusions, multiple protrusions 9-1 to 9-5 will be collectively referred to as multiple protrusions 9. As configurations except for the positions of the multiple protrusions 9, are the same as in the case of the semiconductor device of the first embodiment, the same reference sign will be given to identical portions, and a detailed description will be omitted.

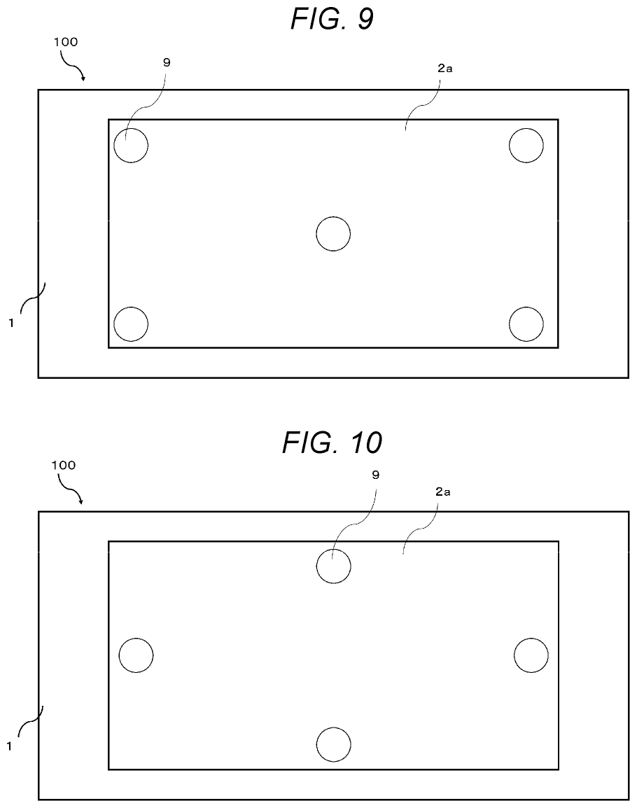

A configuration of a semiconductor device of the fourth embodiment will be described, with reference to FIGS. 9 to 11.

FIG. 9 is a schematic plan view showing one example of a schematic configuration of a semiconductor device according to the fourth embodiment. FIG. 9 is a view of the substrate 1 and the semiconductor chip 2a seen in a direction approximately vertical to the second face of the semiconductor chip 2a. As shown in FIG. 9, the multiple protrusions 9 are provided one each at a center of the semiconductor chip 2a and at corners of the semiconductor chip 2a. In the present embodiment, the semiconductor chip 2a is rectangular, and so multiple protrusions 9 are provided one each at the center and at the four corners of the rectangle.

FIG. 10 is a schematic plan view showing another example of a schematic configuration of a semiconductor device according to the fourth embodiment. FIG. 10 is a view of the substrate 1 and the semiconductor chip 2a seen in a direction approximately vertical to the second face of the semiconductor chip 2a. As shown in FIG. 10, the multiple protrusions 9 may be provided one each at a center of each side of the semiconductor chip 2a.

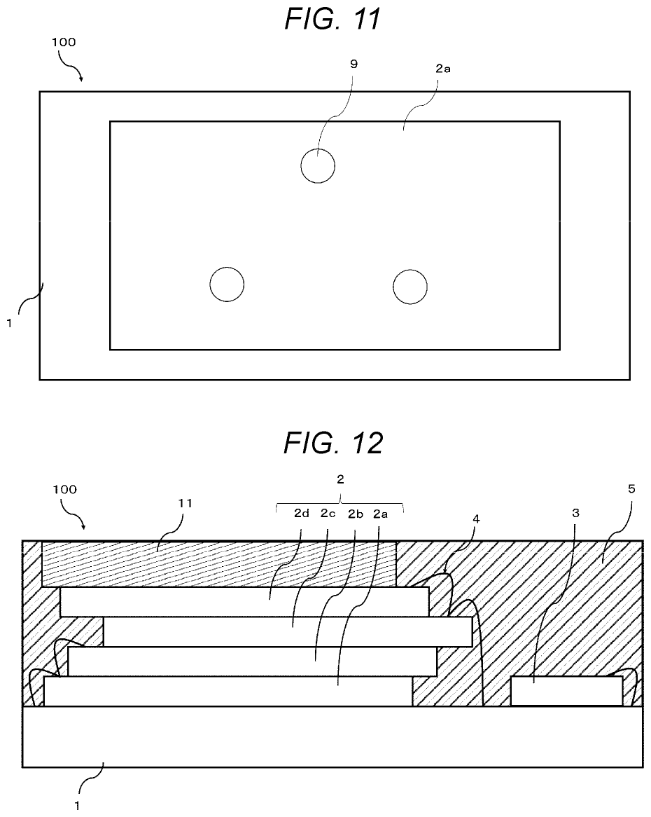

FIG. 11 is a schematic plan view showing still another example of a schematic configuration of a semiconductor device according to the fourth embodiment. FIG. 11 is a view of the substrate 1 and the semiconductor chip 2a seen in a direction approximately vertical to the second face of the semiconductor chip 2a. As shown in FIG. 11, the multiple protrusions 9 are such that at least three protrusions are included. Furthermore, at least three protrusions may be arranged in such a way as to constitute each vertex position of a triangle on the substrate 1 on which the semiconductor chip 2a is provided.

As the protrusions 9 are formed in free spaces without connection pads on the substrate 1 and wiring of the substrate 1, the protrusions 9 need not be formed in the precise positions indicated heretofore. It is sufficient that the protrusions 9 are provided in empty spaces on the substrate 1 near the positions shown in FIGS. 9 to 11. Also, the positions of the protrusions 9 are not limited to the heretofore described positions.

### Advantages

As heretofore described, the fourth embodiment is such that the same advantages as in the first embodiment can be obtained. Also, when assembling a semiconductor device, the second face of the semiconductor chip 2a to which the bonding layer 7 is applied is pressed against the substrate 1, thereby causing the semiconductor chip 2a and the substrate 1 to be bonded. In this process, there is concern that the semiconductor chip 2a will crack due to a force acting on the semiconductor chip 2a in a position in which the protrusion 9 is provided. By causing the positions of the multiple protrusions 9 to be dispersed, as in the present embodiment, a force acting on the semiconductor chip 2a is dispersed, and the possibility of the semiconductor chip 2a cracking can be reduced.

### Fifth Embodiment

Next, a fifth embodiment will be described. The fifth embodiment differs from the first embodiment in that in addition to the protrusion 9, a heat dissipating member is provided in a stacking direction of the semiconductor chip 2. As configurations except for a heat dissipating member being provided in the stacking direction of the semiconductor chip 2 are the same as in the case of the semiconductor device of the first embodiment, the same reference sign will be given to identical portions, and a detailed description will be omitted.

A configuration of a semiconductor device of the fifth embodiment will be described, with reference to FIG. 12.

FIG. 12 is a diagram showing one example of a structure of a semiconductor device according to the fifth embodiment. The semiconductor device 100 shown in FIG. 12 includes the substrate 1, the multiple semiconductor chips 2a, 2b, 2c, and 2d, the memory controller 3, the bonding wire 4, the sealing resin layer 5, and a metal plate 11.

The metal plate 11 is one example of a heat dissipating member, and can dissipate heat of the semiconductor chip 2 from the first face side of the semiconductor chip 2. The metal plate 11 is provided partially overlapping the first face of the semiconductor chip 2d across the bonding layer 7 in the stacking direction of the semiconductor chip 2. At least one portion of the metal plate 11 may be, for example, exposed in the sealing resin layer 5.

### Advantages

According to the fifth embodiment, the same advantages as in the first embodiment can be obtained. Also, according to the present embodiment, the semiconductor device has the metal plate 11 in addition to the protrusion 9, different from the first embodiment. As a result, heat can be dissipated from the first face side in addition to the heat dissipation from the second face side of the semiconductor chip 2, and a further increase in heat dissipating efficiency can be expected. Furthermore, when at least one portion of the metal plate 11 is exposed in the sealing resin layer 5, there is no sealing resin layer 5 on the exposed portion of the metal plate 11. As a result, a more efficient dissipation of heat from the semiconductor device 100 can be expected.

In the first to fifth embodiments, the semiconductor chip 2 is, for example, a two-dimensional NAND memory or 3D NAND memory. The first side of the semiconductor chip 2 is provided with electrode pads, and the second side of the semiconductor chip 2 comprises a semiconductor. However, the second side of the semiconductor chip 2 may comprise an insulator or a metal. The substrate 1 is, for example, a glass epoxy substrate. The insulating layer 6 is, for example, a solder resist. However, the materials of the substrate 1 and the insulating layer 6 are not limited to these. The bonding layer 7 is, for example, a DAF (Die Attach Film). The material of the bonding layer 7 includes, for example, resin. In the first to fifth embodiments, a top surface of the protrusions 9 and a bottom surface of the semiconductor chip 2 are spaced apart. However, if desired, the top surface of the protrusions 9 and the bottom surface of the semiconductor chip 2 may be in direct contact.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a substrate;
an insulating layer that is provided on the substrate and has multiple openings;
a semiconductor chip that is provided on the substrate and has a first face, on which a semiconductor element is formed, and a second face, which is positioned on a side opposite to that of the first face and faces the substrate;
multiple protrusions provided in positions corresponding to the multiple openings of the insulating layer between the substrate and the second face, a height of the multiple protrusions in a direction vertical to the second face is greater than a height of the insulating layer in a direction vertical to the second face; and
a bonding layer that is provided between the substrate and the second face, wherein the bonding layer bonds the substrate and the semiconductor chip, and has a thermal conductivity that is more than 1 W/(m·K) or contains filler of inorganic material.

2. The semiconductor device according to claim 1, wherein the multiple protrusions are each made of metal.

3. The semiconductor device according to claim 2, wherein the multiple protrusions each include one of copper, gold, and tin.

4. The semiconductor device according to claim 2, wherein the multiple protrusions are bumps.

5. The semiconductor device according to claim 2, wherein the multiple protrusions are pillars.

6. The semiconductor device according to claim 2, wherein a surface processing is carried out on the multiple protrusions.

7. The semiconductor device according to claim 6, wherein a surface processing is carried out on the multiple protrusions using nickel and gold.

8. The semiconductor device according to claim 2, wherein the multiple protrusions are each formed in an arch form using a wire.

9. The semiconductor device according to claim 1, further comprising a wiring connected with the multiple protrusions, wherein the wiring is in an electrically floating state or at a ground voltage.

10. The semiconductor device according to claim 1, wherein the multiple protrusions are arranged at positions corresponding to a center of the semiconductor chip and corners of the semiconductor chip.

11. The semiconductor device according to claim 1, wherein the multiple protrusions are arranged at positions corresponding to a center of each side of the semiconductor chip.

12. The semiconductor device according to claim 1, wherein the multiple protrusions are form vertex positions of a triangle seen in a direction vertical to the second face of the semiconductor chip.

13. The semiconductor device according to claim 1, further comprising a heat dissipating member provided on an uppermost semiconductor chip.

14. The semiconductor device according to claim 13, further comprising a sealing resin layer that seals the semiconductor chip, wherein one portion of the heat dissipating member is exposed in the sealing resin layer.

15. A semiconductor device, comprising:
a substrate;
an insulating layer that is provided on the substrate and has a multiple openings;
a semiconductor chip that is provided on the substrate and has a first face, on which a semiconductor element is formed, and a second face, which is positioned on a side opposite to that of the first face and faces the substrate; and
a multiple protrusions provided in positions corresponding to the multiple openings of the insulating layer between the substrate and the second face,
wherein a top surface of at least one of the multiple protrusions and the second surface of the semiconductor chip are spaced apart and separated from each other through the insulating layer.

16. The semiconductor device according to claim 15, further comprising:
a bonding layer that is provided between the substrate and the second face, wherein the bonding layer bonds the substrate and the semiconductor chip, and has a thermal conductivity that is more than 1 W/(m·K).

17. The semiconductor device according to claim 15, further comprising:
a bonding layer that is provided between the substrate and the second face, wherein the bonding layer bonds the substrate and the semiconductor chip, and contains filler of inorganic material.

18. A semiconductor device manufacturing method, comprising:
forming multiple openings in an insulating layer provided on a substrate;
forming multiple protrusions in positions on the substrate corresponding to the multiple openings; and
bonding a semiconductor chip, which has a first face on which a semiconductor element is formed and a second face on a side opposite to that of the first face, onto the substrate in such a way that the second face faces the substrate across the insulating layer,
wherein a top surface of at least one of the multiple protrusions and the second surface of the semiconductor chip are spaced apart and separated from each other through the insulating layer.

19. The semiconductor device manufacturing method according to claim 18, wherein the semiconductor chip is bonded to the substrate using a bonding layer that has a thermal conductivity that is more than 1 W/(m·K).

20. The semiconductor device manufacturing method according to claim 18, wherein the semiconductor chip is bonded to the substrate using a bonding layer that contains filler of inorganic material.
